(19) United States
(12) Patent Application Publication
(10) Pub. No.: US 2007/0126446 A1
(43) Pub. Date: Jun. 7, 2007

(54) Ground-signal-ground (gsg) test structure

(75) Inventor: David M. Szmyd, Austin, TX (US)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V.

(21) Appl. No.: 10/576,714

(22) PCT Filed: Nov. 29, 2004
(86) PCT No.: PCT/IB04/52589

§ 371 Date: Apr. 17, 2006

Related U.S. Application Data
(60) Provisional application No. 60/526,011, filed on Dec. 1, 2003.

(51) Int. Cl. G01R 31/02; H01L 23/58

(52) U.S. Cl. 324/760; 324/765; 257/48

(57) ABSTRACT

A ground-signal-ground (GSG) test structure for production measurement of RF device performance in integrated circuits comprises one pair of signal pads (S1, S2) and two pairs of ground pads (G1a, G1b; G2a, G2b). All the six pads (G1a, G2a, S1, S2, G1b, G2b) are arranged linearly, whereby the width of the structure is small enough for the structure to be placed in a narrow saw lane of a wafer.

The present invention relates to measurement techniques of semiconductor devices, and more particularly, to a ground-signal-ground (GSG) test structure for production measurement of RF device performance in integrated circuits.

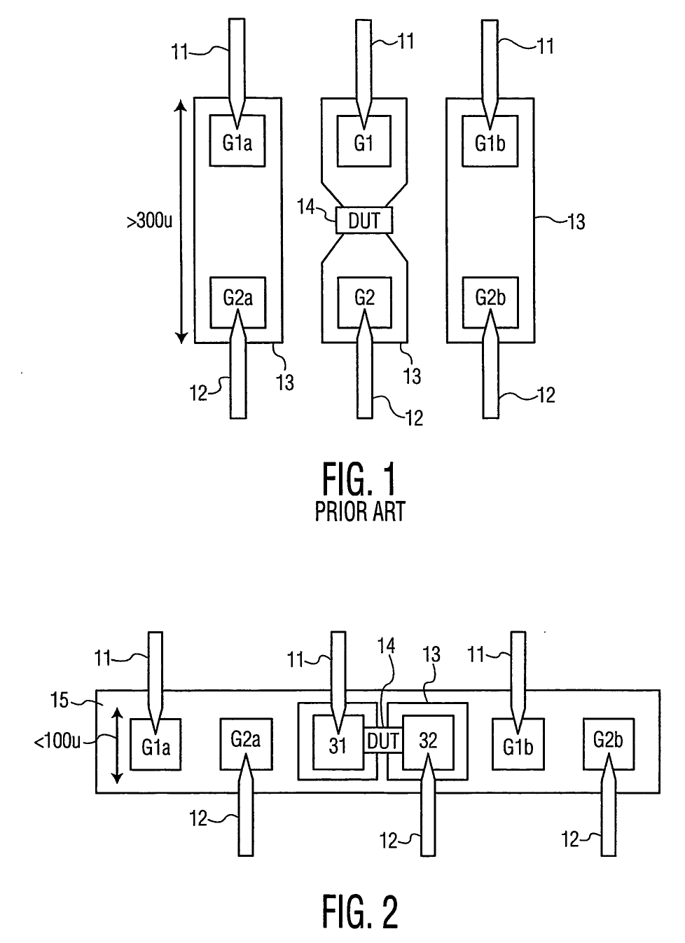

Two-port s-parameter measurements for RF and microwave characterization of semiconductor devices are best made using the ground-signal-ground (GSG) configuration, as typically shown in FIG. 1. This requires six pads organized into a matrix of 2 rows of 3 pads each. As shown in FIG. 1, signal pad S1 is placed between two ground pads G1a and G1b, and all these three pads are connected to a port through RF probes 11. Similarly, signal pad S2 is placed between two ground pads G2a and G2b, and all these three pads are connected to another port through RF probes 12. Each pad is placed in a square opening formed on a: metal layer 13. The device under test (DUT) 14 is placed between the two signal pads S1 and S2.

The GSG test structure shown in FIG. 1 is usually placed in a specially enlarged saw lane between integrated circuit die fields on a production silicon wafer so as to measure the RF device performance of the semiconductor products. The minimum width of such a test structure, however, is 300-400 um. This makes it unsuitable when the saw lane is narrow, which is sometimes less than 100 um. Thus, a specially enlarged saw lane must typically be utilized. Several alternatives have been considered to cope with the problem.

One solution is that the GSG test structure is not placed on production mask test. This, however, has a serious disadvantage in that RF device performance cannot be monitored on product. Nor can RF specification be imposed as part of wafer-level acceptance/scrap criteria. It further necessitates the processing of special non-product silicon with the GSG structure on it to obtain trend data on the RF performance. Such silicon cuts directly into the capacity and profitability of the fabrication plant. Moreover, it only provides trend data, and can never be used to indicate whether individual wafers of product silicon are good or bad.

Another solution is to replace one or more product die fields in the mask reticle with the GSG test structure. This allows for RF monitoring and screening for rejects on production wafers. However, productivity is reduced directly by the number of product die displaced by the test structure. It also gives more GSG test structures per wafer than needed.

A further alternative is to use a drop-in test structure. In this strategy, test structures, including the GSG structure, are grouped separately from the product on the reticle. Normally, only the group containing product die is exposed during the photolithography step. At certain pre-determined places on the wafer, the group of test structures is instead exposed, or “dropped in” in place of product die. However, because the product and test group share space on the same reticle, light passing through the one not being exposed must be blocked. Also, the product field is smaller as it no longer occupies the full reticle field. This complicates the mask generation and photolithography steps, and reduces throughput in the factory. It also makes testing more complex.

Therefore, there is a need of a better solution for implementing s-parameter GSG measurement in a narrow saw lane of the wafer with less complexity.

To realize the above, the present invention provides a new arrangement of ground-signal-ground (GSG) test structure which comprises one pair of signal pads and two pairs of ground pads. In particular, all the six pads are arranged linearly. Thus, the width of the structure can be less than 100 um, and the structure is suitable to be placed in a narrow saw lane of the width normally utilized in production runs.

The above and other features and advantages of the present invention will be clearer after reading the detailed description of the preferred embodiments of the present invention, with reference to the accompanying drawings, in which:

FIG. 1 is the arrangement of the GSG test structure of prior art; and

FIG. 2 is the arrangement of the GSG test structure according to the present invention.

As shown in FIG. 2, according to present invention, all the six pads of the two-port s-parameter GSG test structure are arranged linearly, instead of the 2×3 matrix configuration as in the prior art shown in FIG. 1.

In particular, the pair of signal pads S1, S2 are placed between two pairs of ground pads G1a, G2a and G1b, G2b, and all the six pads G1a, G2a, S1, S2, G1b, G2b are arranged linearly, as shown in FIG. 2. The width of the structure can be less than 100 um, as compared to 300 um or more in the prior art, thus making the structure suitable to be placed in a narrow saw lane to test the performance of the semiconductor device on product.

As shown in FIG. 2, the ground pads G1a and G1b, as well as the signal pad S1 are connected to one port through RF probes 11, and the ground pads G2a and G2b, as well as the signal pad S2 are connected to another port through RF probes 12.

The pair of signal pads S1 and S2 are placed on an upper metal layer 13, and a device under test (DUT) 14 is placed between the two signal pads S1 and S2.

The pairs of the ground pads G1a, G2a, G1b, G2b are placed on a lower metal layer 15 which crosses under the upper metal layer 13, thus the ground path can be brought directly next to the device 14 by the lower layer 15. This has the advantage supplying a low resistance ground shield under the signal pad, giving a more noise-free measurement.

In an embodiment, the pitch between pads is around 100 um and the pitch between probes is around 200 um.

Though the above has described the preferred embodiment of the present invention, it shall be appreciated that other modifications, variations and changes are possible to a person skilled in the art without departing the spirit of the present invention. For example, the ground pads G1a and G2a can have a common single rectangular pad opening, as contrary to the square openings shown in FIG. 1. This also applies to ground pads G1b and G2b. Thus, the protection scope of the present invention is solely intended to be defined in the accompanying claims.

What is claimed is:

1. A ground-signal-ground (GSG) test structure for production measurement of RF device performance in integrated circuits, comprising one pair of signal pads (S1, S2) and two pairs of ground pads (G1a, G2a; G1b, G2b), wherein all said six pads (G1a, G2a, S1, S2, G1b, G2b) are arranged linearly.

2. The test structure of claim 1, wherein each of said pairs (G1a, G2a; S1, S2; G1b, G2b) comprising a first pad (G1a, S1, G1b) connected to a first RF probe (11) and a second pad (G2a, S2, G2b) connected to a second RF probe (12).

3. The test structure of claim 2, wherein all said first RF probes (11) are connected to a first port, and all said second RF probes (12) are connected to a second port.

4. The test structure of claim 3, wherein said pair of signal pads (S1, S2) is located between, said two pairs of ground pads (G1a, G1b; G2a, G2b).

5. The test structure of claim 4, wherein said first pads (G1a, S1, G1b) and said second pads (G2a, S2, G2b) are positioned alternately.

6. The test structure of claim 5, wherein a device under test (DUI) (14) is placed between said pair of signal pads (S1, S2).

7. The test structure of claim 6, wherein said pair of signal pads (S1, S2) are placed on an upper metal layer (13) and said two pairs of ground pads (G1a, G1b; G2a, G2b) are placed on a lower metal layer (15).

8. The test structure of claim 7, wherein each of said two pairs of ground pads (G1a, G2a; G1b, G2b) has a common single pad opening.

9. The test structure of claim 8, wherein a pad pitch is 100 um and a probe pitch is 200 um.

10. An arrangement of GSG testing pads comprising one pair of signal pads (S1, S2) and two pairs of ground pads (G1a, G1b; G2a, G2b), wherein all of said pads (G1a, G2a, S1, S2, G1b, G2b) are arranged linearly.

11. The arrangement of claim 10, wherein all of said pads (G1a, G2a, S1, S2, G1b, G2b) are placed in a saw lane of a wafer.

12. The arrangement of claim 11, wherein said pair of signal pads (S1, S2) is located between said two pairs of ground pads (G1a, G1b; G2a, G2b).

13. The arrangement of claim 12, wherein each of said pairs (G1a, G2a; S1, S2; G1b, G2b) comprises a first pad (G1a, S1, G1b) connected to a first RF probe (11) and a second pad (G2a, S2, G2b) connected to a second RF probe (12).

14. The arrangement of claim 13, wherein all said first RF probes (11) are connected to a first port, and all said second RF probes (12) are connected to a second port.

15. The arrangement of claim 14, wherein said first pads (G1a, S1, G1b) and said second pads (G2a, S2, G2b) are positioned alternately.
